(19) United States
(12) Patent Application Publication
(10) Pub. No.: US 2013/0092226 A1
(43) Pub. Date: Apr. 18, 2013

(54) MULTILAYER FILM BACKING FOR PHOTOVOLTAIC MODULES

(71) Applicants: Andreas Pawlik, Recklinghausen (DE); Martin Wielpuetz, Senden (DE); Michael Beyer, Raesfeld (DE)

(72) Inventors: Andreas Pawlik, Recklinghausen (DE); Martin Wielpuetz, Senden (DE); Michael Beyer, Raesfeld (DE)

(21) Appl. No.: 13/649,319

(22) Filed: Oct. 11, 2012

(30) Foreign Application Priority Data
Oct. 14, 2011 (DE) 10 2011 084 519.4

(51) Int. Cl. B32B 7/02; B32B 27/32; H01L 31/18; B32B 27/38; B32B 27/42; H01L 31/0216; B32B 27/34; B32B 27/08

(52) U.S. Cl. 136/256; 428/474.7; 428/339; 428/216; 428/215; 428/212; 428/447; 428/413; 428/423.5; 428/423.3; 438/64; 257/E31.117

(57) ABSTRACT

A multilayer film suitable as a backing for a photovoltaic module is provided. The film comprises, in the order listed: a) a layer of a moulding composition which comprises at least 35% by weight, based on the overall layer moulding composition, of polyamide; b) a layer of a moulding composition which comprises at least 50% by weight, based on the overall layer moulding composition, of a polymer fraction consisting of: I) 30 to 95 parts by weight of polyamide and II) 5 to 70 parts by weight of polyolefin, where a sum of I) and II) in parts by weight is 100; and c) a layer of a moulding composition which comprises at least 35% by weight, based on the overall moulding composition, of polyamide; wherein at least one of layers a), b) and c) further comprises a polyamide elastomer which is a polyetheresteramide, a polyetheramide or a combination thereof.

### CROSS REFERENCE TO RELATED APPLICATIONS

This application claims priority to DE 102011084519.4 filed Oct. 14, 2011, the disclosure of which is incorporated herein by reference in its entirety.

### BACKGROUND OF THE INVENTION

The invention relates a multilayer film with improved adhesion as a back cover for solar modules.

Solar modules, frequently also referred to as photovoltaic modules, serve for electrical power generation from sunlight and consist of a laminate which comprises a solar cell system as the core layer. This core layer is encased with encapsulation materials which serve as protection against mechanical and weathering-related influences.

In conventional solar modules, the active solar cell is positioned between a front cover and a back cover. The front cover is transparent, generally consists of glass; and is bonded by means of an adhesion promoter layer which often contains an ethylene-vinyl acetate copolymer to the layer comprising the solar cell. The back cover provides electric shielding, serves as protection against weathering influences such as UV light and acts as a moisture barrier.

Film composites composed of fluoropolymer films and polyester may conventionally be employed as a back cover. The fluoropolymer film on the outside provides weathering resistance, while the polyester film is utilized to obtain mechanical stability and electrical insulation properties. A further fluoropolymer film on the inside serves for attachment to the sealing layer of the solar cell system. However, such fluoropolymer films have only low adhesion to the sealing layer which is used as embedding material for the solar cells themselves. In addition, the fluoropolymer film contributes to electrical insulation only to a minor degree, which results in the need to use a comparatively thick polyester film.

WO 2008138022 therefore proposes replacing the two fluoropolymer films in such composites with films of nylon-12 (PA12). In a development thereof, WO 2011066595 proposes that the solar cell-facing thermoplastic layer comprise a light-reflecting filler such as titanium dioxide, while the solar cell-remote thermoplastic layer comprise a second filler such as glass fibres, wollastonite or mica, which brings about a higher thermal conductivity of this layer. Illustrative thermoplastics come from the group of the polyamides, polyesters blends of polyamide and polyolefin. Explicit mention is made of PA11 PA12 and PA1010, and blends thereof with polyolefins.

Photovoltaic modules may have service lives of at least 20 years, and during this period, the interlaminar adhesion must be very substantially maintained. This applies firstly to the binding of the backing film to the sealing layer containing the actual solar cell, and secondly also to the adhesion of the individual layers of the backing film to one another. When the same polyamide is used in the polymer fraction of the backing film in all layers, very good adhesion may generally be achieved. However, for reasons of cost economy, the polymer fraction of the middle layer often consists of blends of polyamides and polyolefins. Such composites can, as a result of the polyolefin content, have a relatively low starting level of adhesion; more particularly, however, the adhesion level falls to a greater degree with time, compared to pure polyamide systems.

### SUMMARY OF THE INVENTION

It is therefore an object of the invention to provide a multilayer film having improved adhesion between purely polyamide-based layers and those comprising polyamide and polyolefin.

Another object of this invention is to provide a multilayer film which is suitable as a backing film of a photovoltaic module.

A further object of the invention is to provide a photovoltaic module having improved stability of layers.

These and other objects have been achieved by the present invention, the first embodiment of which includes a multilayer film, comprising, in the order listed:

a) a layer of a moulding composition which comprises at least 35% by weight, based on the overall layer moulding composition, of polyamide;

b) a layer of a moulding composition which comprises at least 50% by weight, based on the overall layer moulding composition, of a polymer fraction consisting of:

I) 30 to 95 parts by weight of polyamide and

II) 5 to 70 parts by weight of polyolefin,

where a sum of I) and II) in parts by weight is 100; and

c) a layer of a moulding composition which comprises at least 35% by weight, based on the overall moulding composition, of polyamide;

wherein

at least one of layers a), b) and c) further comprises a component selected from the group consisting of:

layer a) further comprises from 1 to 25% by weight of the layer composition of a polyamide elastomer which is a polyetheresteramide, a polyetheramide or a combination thereof,

layer b) further comprises 1 to 15% by weight of the layer composition of polyamide elastomer which is a polyetheresteramide, a polyetheramide or a combination thereof, and

layer c) further comprises from 1 to 25% by weight of the layer composition of a polyamide elastomer which is a polyetheresteramide, a polyetheramide or a combination thereof.

In a preferred embodiment a thickness of the layer b) of the multilayer film is from 100 to 500 μm.

In another preferred embodiment, the polyamide elastomer of the multilayer film comprises a polyetheresteramide which comprises from 4 to 60% by weight of a polyether of a diol selected from the group consisting of 1,2-ethanediol, 1,2-propanediol, 1,3-propanediol, 1,4-butanediol and 1,3-butanediol.

In a further preferred embodiment the polyamide elastomer of the multilayer film comprises a polyetheramide which comprises from 4 to 60% by weight of a polyamine obtained from a diol selected from the group consisting of 1,2-ethanediol, 1,2-propanediol, 1,3-propanediol, 1,4-butanediol and 1,3-butanediol.

In a highly preferred embodiment, the present invention provides a photovoltaic module, comprising;

a solar cell embedded in a sealing layer; and

the multilayer film according to claim 1 as a back cover;

wherein the layer a) of the laminate film is bonded to the sealing layer.

### DETAILED DESCRIPTION OF THE INVENTION

The multilayer film according to the present invention comprises, in the order listed:

a) a layer of a moulding composition which comprises at least 35% by weight, based on the overall layer moulding composition, of polyamide;

b) a layer of a moulding composition which comprises at least 50% by weight, based on the overall layer moulding composition, of a polymer fraction consisting of:

I) 30 to 95 parts by weight of polyamide and

II) 5 to 70 parts by weight of polyolefin,

where a sum of I) and II) in parts by weight is 100; and

c) a layer of a moulding composition which comprises at least 35% by weight, based on the overall moulding composition, of polyamide;

wherein

at least one of layers a), b) and c) further comprises a component selected from the group consisting of:

layer a) further comprises from 1 to 25% by weight preferably 2 to 20% by weight of the layer composition of a polyamide elastomer which is a polyetheresteramide, a polyetheramide or a combination thereof,

layer b) further comprises 1 to 15% by weight more preferably 2 to 10% by weight of the layer composition of polyamide elastomer which is a polyetheresteramide, a polyetheramide or a combination thereof, and

layer c) further comprises from 1 to 25% preferably 2 to 20% by weight of the layer composition of a polyamide elastomer which is a polyetheresteramide, a polyetheramide or a combination thereof.

In the layer a) the polyamide content may preferably be preferably at least 40% by weight, more preferably at least 45% by weight, especially preferably at least 50% by weight, and most preferably at least 55% by weight, based in each case on the overall moulding composition of the a) layer.

In the layer b) the polyamide content may preferably be at least 35% by weight, and more preferably at least 40% by weight of the polymer fraction consisting of polyamide I) and polyolefin II.

In the layer c) the polyamide content may preferably be at least 40% by weight, more preferably at least 45% by weight, especially preferably at least 50% by weight and most preferably at least 55% by weight, based in each case on the overall moulding composition,

Thus, various embodiments are possible:

In a first embodiment, polyamide elastomer may be present only in the layer according to a).

In a second embodiment, polyamide elastomer may be present only in the layer according to b).

In a third embodiment, polyamide elastomer may be present only in the layer according to c).

In a fourth embodiment, polyamide elastomer may be present both in the layer according to a) and in the layer according to c).

In a fifth embodiment, polyamide elastomer may be present both in the layer according to a) and in the layer according to b).

In a sixth embodiment, polyamide elastomer may be present both in the layer according to b) and in the layer according to c).

In a seventh embodiment, polyamide elastomer may be present both in the layer according to a) and in the layers according to b) and c).

Unless stated otherwise, the further details which follow apply equally to all these embodiments.

The polyamide may be a partly crystalline polyamide, for example PA6, PA66, PA610, PA612, PA10, PA810, PA106, PA1010, PA11, PA1011, PA1012, PA1210, PA1212, PA814, PA1014, PA618, PA512, PA613, PA813, PA914, PA1015, PA11, PA12, or a semiaromatic polyamide, called a polyphthalamide (PPA). (The naming of the polyamides corresponds to the international standard, the first number(s) giving the number of carbon atoms of the starting diamine and the last number(s) the number of carbon atoms of the dicarboxylic acid. If only one number is mentioned, this means that the starting material was an α,ω-aminocarboxylic acid or the lactam derived therefrom; for the rest, reference is made to H. Domininghaus, Die Kunststoffe and ihre Eigenschaften [The polymers and their properties], pages 272 ff., VDI-Verlag, 1976.) Suitable PPAs are, for example, PA66/6T, PA6/6T, PA6T/MPMDT (MPMD stands for 2-methylpentamethylenediamine), PA9T, PA10T, PA11T, PA12T, PA14T and copolycondensates of these latter types with an aliphatic diamine and an aliphatic dicarboxylic acid or with an ω-aminocarboxylic acid or a lactam. Partly crystalline polyamides have an enthalpy of fusion of more than 25 J/g, measured by the DSC method to ISO 11357 in the 2nd heating step and integration of the melt peak.

The polyamide may also be a semicrystalline polyamide. Semicrystalline polyamides have an enthalpy of fusion of 4 to 25 J/g, measured by the DSC method to ISO 11357 in the 2nd heating step and integration of the melt peak. Examples of suitable semicrystalline polyamides are
The polyamide of 1,10-decanedioic acid or 1,12-dodecanedioic acid and 4,4′-diaminodicyclohexylmethane (PA PACM10 and PA PACM12), proceeding from a 4,4′-diaminodicyclohexylmethane with a trans,trans isomer content of 35 to 65%;
copolymers based on the abovementioned partly crystalline polyamides; and
blends of the abovementioned partly crystalline polyamides and a compatible amorphous polyamide.

The polyamide may also be an amorphous polyamide. Amorphous polyamides have an enthalpy of fusion of less than 4 J/g, measured by the DSC method to ISO 11357 in the 2nd heating step and integration of the melt peak. Examples of amorphous polyamides are:
the polyamide of terephthalic acid and/or isophthalic acid and the isomer mixture of 2,2,4- and 2,4,4-trimethylhexamethylenediamine,
the polyamide of isophthalic acid and 1,6-hexamethylenediamine,
the copolyamide of a mixture of terephthalic acid/isophthalic acid and 1,6-hexamethylenediamine, optionally in a mixture with 4,4′-diaminodicyclohexylmethane,
the copolyamide of terephthalic acid and/or isophthalic acid, 3,3′-dimethyl-4,4′-diaminodicyclohexylmethane and laurolactam or caprolactam,
the (co)polyamide of 1,12-dodecanedioic acid or sebacic acid, 3,3′-dimethyl-4,4′-diaminodicyclohexylmethane, and optionally laurolactam or caprolactam,
the copolyamide of isophthalic acid, 4,4′-diaminodicyclohexylmethane and laurolactam or caprolactam,
the polyamide of 1,12-dodecanedioic acid and 4,4′-diaminodicyclohexylmethane (in the case of a low trans,trans isomer content),
the (co)polyamide of terephthalic acid and/or isophthalic acid and an alkyl-substituted bis(4-aminocyclohexyl)methane homologue, optionally in a mixture with hexamethylenediamine,
the copolyamide of bis(4-amino-3-methyl-5-ethylcyclohexyl)methane, optionally together with a further diamine, and isophthalic acid, optionally together with a further dicarboxylic acid,
the copolyamide of a mixture of m-xylylenediamine and a further diamine, e.g. hexamethylenediamine, and isophthalic acid, optionally together with a further dicarboxylic acid, for example terephthalic acid and/or 2,6-naphthalenedicarboxylic acid,
the copolyamide of a mixture of bis(4-aminocyclohexyl)methane and bis(4-amino-3-methylcyclohexyl)methane, and aliphatic dicarboxylic acids having 8 to 14 carbon atoms, and
polyamides or copolyamides of a mixture comprising 1,14-tetradecanedioic acid and an aromatic, arylaliphatic or cycloaliphatic diamine.

These examples may be varied to a very substantial degree by addition of further components (for example caprolactam, laurolactam or diamine/dicarboxylic acid combinations) or by partial or full replacement of starting components by other components.

The polyolefin of the layer according to b) may be, for example, polyethylene or polypropylene. In principle, any commercial type may be used. For example, the following are useful: high-, medium- or low-density linear polyethylene, LDPE, isotactic or atactic homopolypropylene, random copolymers of propene with ethene and/or 1-butene, ethylene-propylene block copolymers and the like. The polyolefin may also comprise an impact-modifying component, for example EPM or EPDM rubber or SEBS; it can be prepared by any known process, for example according to Ziegler-Natta, by the Phillips process, by means of metallocenes or by free-radical means.

For better attachment to the polyamide, the polyolefin may contain functional groups; additionally or alternatively thereto, a compatibilizer may be added. Examples of suitable functional groups may include acid anhydride groups, N-acyllactam groups, carboxylic acid groups, epoxide groups, oxazoline groups, trialkoxysilane groups, or hydroxyl groups. The functional groups may be introduced here either by copolymerization of a suitable monomer together with the olefin, or by a graft reaction. In the graft reaction, a preformed polyolefin may be reacted in a known manner with an unsaturated functional monomer and advantageously a free-radical donor at elevated temperature.

Polyetheresteramides are described for example in DE-A-25 23 991 and DE-A-27 12 987; they contain a polyetherdiol as a comonomer. Polyetheramides are described, for example in DE-A-30 06 961; they contain a polyetherdiamine as a comonomer.

In the polyetherdiol or the polyetherdiamine, the polyether unit may be based, for example on 1,2-ethanediol, 1,2-propanediol, 1,3-propanediol, 1,4-butanediol or 1,3-butanediol. The polyether unit may also have a mixed structure, for instance with random or blockwise distribution of the units which originate from the diols. The weight-average molar mass of the polyetherdiols or polyetherdiamines is 200 to 5000 g/mol and preferably 400 to 3000 g/mol; a proportion thereof in the polyetheresteramide or polyetheramide is preferably 4 to 60% by weight and more preferably 10 to 50% by weight. Suitable polyetherdiamines are obtainable by conversion of the corresponding polyetherdiols by reductive amination or coupling onto acrylonitrile with subsequent hydrogenation. They are available, for example, in the form of the JEFFAMINE® D or ED types, or the ELASTAMINE® types from Huntsman Corp. or in the form of the Polyetheramine D series from BASF SE. It is also possible to use smaller amounts of a polyethertriamine, for example a JEFFAMINE® T type, if a branched polyetheramide is to be used. Preference may be given to using polyetherdiamines or polyethertriamines which contain an average of at least 2.3 carbon atoms in the chain per ether oxygen atom. According to the invention, preference may be given to polyetheramides owing to better hydrolysis stability.

The moulding composition of the layer according to a) may contain either one of the abovementioned polyamides or two or more thereof as a mixture. In addition, up to 40% by weight, based on the overall polymer content of the moulding composition, of other thermoplastics may be present, for example impact-modifying rubbers. Any rubbers present preferably contain, in accordance with conventional knowledge, functional groups with which compatibility with the polyamide matrix may be obtained. In addition, the assistants and additives customary for polyamides may be present, especially light and/or heat stabilizers, or preferably also light-reflecting fillers, for example titanium dioxide (WO 2011066595).

The moulding composition of the layer according to b), may, as well as polyamide, contain either one of the abovementioned polyolefins or two or more thereof as a mixture. In addition, the assistants and additives customary for polyamide and polyolefin moulding compositions may be present, especially light and/or heat stabilizers, light-reflecting fillers, for example, titanium dioxide, and reinforcing fillers, for example, glass fibres, wollastonite or mica.

For the moulding composition of the layer according to c), the same applies as to the moulding composition of the layer according to a), and also, with regard to fillers, the same as for the moulding composition of the layer according to b). In addition, the moulding composition of the layer according to c) may be coloured and/or comprise a matting agent.

The individual film layers may generally have the following thicknesses:
layers according to a) and c): 15 to 100 μm and preferably 25 to 50 μm;
layer according to b): 100 to 500 μm and preferably 150 to 400 μm.

The multilayer film used in accordance with the invention may be produced by conventionally known methods, such as for example, coextrusion or lamination.

The invention also provides for the use of the laminate film as a back cover of a photovoltaic module. For this purpose, the layer according to a) may be bonded, for example by lamination or adhesion, to the sealing layer into which the solar cell has been embedded. Owing to the proportion of polyamide or polyamide elastomer in the layer according to a), the lamination affords good adhesion to the sealing layer. The sealing layer used may be any material conventionally known for such utility.

The invention further provides a photovoltaic module which comprises the multilayer laminate film as described above as a back cover, with bonding of the layer according to a) to the sealing layer into which the solar cell has been embedded.

Having generally described this invention, a further understanding can be obtained by reference to certain specific examples which are provided herein for purposes of illustration only, and are not intended to be limiting unless otherwise specified.

### EXAMPLES

The following moulding compositions were produced; “parts” are always parts by weight:

### Compound 1 for Outer Layers

79.25 parts of VESTAMID® L1901 nf (PA12), 0.5 part of IRGANOX® 1098 (a sterically hindered phenolic antioxidant), 0.2 part of TINUVIN® 312 (UV absorber) and 20 parts of the titanium dioxide Sachtleben R 420 were mixed with the aid of a twin-shaft extruder (Coperion Werner & Pfleiderer ZSK 25 WLE, 36 L/D) at a barrel temperature of 220° C. The extrudate was cooled with the aid of a water bath and chopped; the pellets were subsequently dried in a forced-air oven at 80° C. for 12 hours.

### Compound 2 for Outer Layers

71.75 parts of VESTAMID® L1901 nf, 7.5 parts of a polyetheresteramide (prepared from 63.796% by weight of laurolactam, 6.645% by weight of dodecanedioic acid, 29.492% by weight of polytetrahydrofuran (PTHF 1000) and 0.067% by weight of 50% hypophosphorous acid), 0.5 part of IRGANOX® 1098, 0.2 part of TINUVIN® 312 and 20 parts of the titanium dioxide Sachtleben R 420 were mixed with the aid of a twin-shaft extruder (Coperion Werner & Pfleiderer ZSK 25 WLE, 36 L/D) at a barrel temperature of 220° C. The extrudate was cooled with the aid of a water bath and chopped; the pellets were subsequently dried in a forced-air oven at 80° C. for 12 hours.

### Compound 3 for Outer Layers

64.25 parts of VESTAMID® L1901 nf, 15 parts of the same polyetheresteramide as in Compound 2, 0.5 part of IRGANOX® 1098, 0.2 part of TINUVIN® 312 and 20 parts of the titanium dioxide Sachtleben R 420 were mixed with the aid of a twin-shaft extruder (Coperion Werner & Pfleiderer ZSK 25 WLE, 36 L/D) at a barrel temperature of 220° C. The extrudate was cooled with the aid of a water bath and chopped; the pellets were subsequently dried in a forced-air oven at 80° C. for 12 hours.

### Compound 4 for Middle Layer

50.6 parts of VESTAMID® L1901, 26 parts of MOPLEN HP552L (homopolypropylene, extrusion type), 20 parts of TEC 110 kaolin, 3 parts of KRATON® FG1901 (a maleic anhydride-modified styrene-ethylene/butylene block copolymer) and 0.4 part of IRGANOX® 1098 were mixed with the aid of a twin-shaft extruder (Coperion Werner & Pfleiderer ZSK 25 WLE, 36 L/D) at a barrel temperature of 200° C. The extrudate was cooled with the aid of a water bath and chopped; the pellets were subsequently dried in a forced-air oven at 80° C. for 12 hours.

### Extrusion of Three-Layer Films

A multilayer film system from Collin (300 mm slot die, 0-6 mm gap, co-extrusion feed block for 3-layer or 5-layer films) was used to produce three-layer films at a processing temperature of approx. 230° C. The middle layer was set to 250 μm, and each of the other layers to 50 μm. The results are shown in Table 1.

TABLE 1
Examples

| | | Interlaminar |
|---|---|---|
| | Layer structure | adhesion [N/mm] |
| Comparative | Compound 1/Compound 4/Compound 1 | 2.2 |
| example | | |
| Example 1 | Compound 2/Compound 4/Compound 2 | 3.2 |
| Example 2 | Compound 3/Compound 4/Compound 3 | 3.5 |

Numerous modifications and variations on the present invention are possible in light of the above description. It is therefore to be understood that within the scope of the appended claims, the invention may be practiced otherwise than as specifically described herein.

1. A multilayer film, comprising, in the order listed:
a) a layer of a moulding composition which comprises at least 35% by weight, based on the overall layer moulding composition, of polyamide;
b) a layer of a moulding composition which comprises at least 50% by weight, based on the overall layer moulding composition, of a polymer fraction consisting of:
I) 30 to 95 parts by weight of polyamide and
II) 5 to 70 parts by weight of polyolefin,
where a sum of I) and II) in parts by weight is 100; and
c) a layer of a moulding composition which comprises at least 35% by weight, based on the overall moulding composition, of polyamide;
wherein
at least one of layers a), b) and c) further comprises a component selected from the group consisting of:
layer a) further comprises from 1 to 25% by weight of the layer composition of a polyamide elastomer which is a polyetheresteramide, a polyetheramide or a combination thereof,
layer b) further comprises 1 to 15% by weight of the layer composition of polyamide elastomer which is a polyetheresteramide, a polyetheramide or a combination thereof, and
layer c) further comprises from 1 to 25% by weight of the layer composition of a polyamide elastomer which is a polyetheresteramide, a polyetheramide or a combination thereof.

2. The multilayer film according to claim 1, wherein
a thickness of the layer b) is from 100 to 500 μm.

3. The multilayer film according to claim 1, wherein
a thickness of the layer a) and the layer c) is from 15 to 100 μm.

4. The multilayer film according to claim 2, wherein
a thickness of the layer a) and the layer c) is from 15 to 100 μm.

5. The laminate film according to claim 1, wherein
the polyamide comprises at least one selected from the group consisting of a partly crystalline polyamide having an enthalpy of fusion of more than 25 J/g, a semicrystalline polyamide having an enthalpy of fusion of from 4 to 25 J/g and an amorphous polyamide having an enthalpy of fusion of less than 4 J/g.

6. The multilayer film according to claim 1, wherein the polyolefin comprises one selected from the group consisting of high-, medium- or low-density linear polyethylene, isotactic or atactic homopolypropylene, a random copolymer of propene with ethene, a random copolymer of propene, ethene and 1-butene, and an ethylene-propylene block copolymer any of which optionally comprising an impact-modifying component.

7. The multilayer film according to claim 1, wherein the polyolefin comprises a functional group selected from the group consisting of an acid anhydride group, an N-acyllactam group, a carboxylic acid group, an epoxide group, an oxazoline group, a trialkoxysilane group, and a hydroxyl group.

8. The multilayer film according to claim 1 wherein the polyamide elastomer comprises a polyetheresteramide which comprises from 4 to 60% by weight of a polyether of a diol selected from the group consisting of 1,2-ethanediol, 1,2-propanediol, 1,3-propanediol, 1,4-butanediol and 1,3-butanediol.

9. The multilayer film according to claim 1 wherein the polyamide elastomer comprises a polyetheramide which comprises from 4 to 60% by weight of a polyamine obtained from a diol selected from the group consisting of 1,2-ethanediol, 1,2-propanediol, 1,3-propanediol, 1,4-butanediol and 1,3-butanediol.

10. The multilayer film according to claim 1 wherein the layer a), the layer c) or both layer a) and layer c) further comprise an impact-modifying rubber optionally modified with a polyamide compatible functional group.

11. A photovoltaic module, comprising;
a solar cell embedded in a sealing layer; and
the multilayer film according to claim 1 as a back cover;
wherein the layer a) of the multilayer film is bonded to the sealing layer.

12. The photovoltaic module according to claim 11,
wherein a thickness of the layer b) is from 100 to 500 μm.

13. The photovoltaic module according to claim 11,
wherein a thickness of the layer a) and the layer c) is from 15 to 100 μm.

14. The photovoltaic module according to claim 12,
wherein a thickness of the layer a) and the layer c) is from 15 to 100 μm.

15. The photovoltaic module according to claim 11, wherein the polyamide elastomer comprises a polyetheresteramide which comprises from 4 to 60% by weight of a polyether of a diol selected from the group consisting of 1,2-ethanediol, 1,2-propanediol, 1,3-propanediol, 1,4-butanediol and 1,3-butanediol.

16. The photovoltaic module according to claim 11, wherein the polyamide elastomer comprises a polyetheramide which comprises from 4 to 60% by weight of a polyamine obtained from a diol selected from the group consisting of 1,2-ethanediol, 1,2-propanediol, 1,3-propanediol, 1,4-butanediol and 1,3-butanediol.

17. The photovoltaic module according to claim 11, wherein the layer a), the layer c) or both layer a) and layer c) further comprise an impact-modifying rubber optionally modified with a polyamide compatible functional group.

18. A method to prepare a photovoltaic module, comprising:
bonding the layer a) of the multilayer film according to claim 1 to a sealing layer comprising a solar cell.
